(19) United States
(12) Patent Application Publication
(10) Pub. No.: US 2024/0118577 A1
(43) Pub. Date: Apr. 11, 2024

(54) WIRELESS ELECTROCHROMIC INSULATED GLASS UNIT

(71) Applicant: GuRu Wireless, Inc., Pasadena, CA (US)

(72) Inventors: Behrooz Abiri, Pasadena, CA (US); Narbeh Derhacobian, Pasadena, CA (US)

(21) Appl. No.: 18/243,645

(22) Filed: Sep. 7, 2023

Related U.S. Application Data
(60) Provisional application No. 63/421,474, filed on Nov. 1, 2022.
(60) Provisional application No. 63/404,457, filed on Sep. 7, 2022.

(51) Int. Cl. G02F 1/163; G02F 1/1333; G02F 1/1343; G02F 1/153; H01Q 1/22; H02S 40/20

(52) U.S. Cl. CPC G02F 1/163; G02F 1/133325; G02F 1/133345; G02F 1/1343; G02F 1/1533; H01Q 1/2208; H02S 40/20

(57) ABSTRACT

An insulated glass unit includes, in part, a first window pane that includes an electrochromic coating, and a second window pane spaced away from the first window pane. The second window pane includes, in part, a multitude of antennas adapted to receive RF signals, a rectifying circuit adapted to convert the RF signals received by the multitude of planar antennas to a DC power, and a controller adapted to change an opacity of the electrochromic coating using the converted DC power.

### RELATED APPLICATION

The present application claims benefit under 35 USC 119(e) of U.S. Application No. 63/404,457, filed Sep. 7, 2022, and U.S. application No. 63/421,474, filed Nov. 1, 2022, the contents of both which are incorporated herein by reference in their entirety.

### TECHNICAL FIELD

The present application relates to an electrochromic glass, and more particularly to a method and system for wirelessly changing the tint level of an electrochromic glass.

### BACKGROUND

Electrochromic glass windows have been used to improve the energy efficiency of a building by reducing indoor lighting and managing the temperature as well as the energy consumption of the building. An electrochromic (EC) glass has an adjustable tint level that can be controlled based on the outdoor weather. The tint level may be changed to control the transparency and/or reflectivity of the glass, and thereby allow or block solar light and/or infrared rays from entering the building. By controlling the amount of light that enters or is blocked from entering through the EC glass, energy saving may be achieved in heating the building during the winter, or cooling the building during the summer.

### SUMMARY

An insulated glass unit, in accordance with one embodiment of the present disclosure includes, in part, a first window pane that includes an electrochromic coating; and a second window pane spaced away from the first window pane. The second window pane includes, in part, a multitude of antennas adapted to receive RF signals; a rectifying circuit adapted to convert the RF signals received by the multitude of planar antennas to a DC power; and a controller adapted to change an opacity of the electrochromic coating using the converted DC power.

In one embodiment, the multitude of antennas are disposed on a first surface of the second window pane exposed to an interior of a room in which the insulated glass unit is adapted to be installed. The rectifying circuit and the controller may be disposed on a second surface of the second window pane. In one embodiment, the multitude of antennas are disposed, the rectifying circuit and the controller are disposed on a surface of the second window pane within a space separating the first window pane from the second window pane.

In one embodiment, the multitude of antennas are formed using a transparent conductive metal layer. In one embodiment, the rectifying circuit and the controller are disposed in a frame of the insulated glass unit. In one embodiment, the multitude of antennas are disposed in the frame of the insulated glass unit.

In one embodiment, the multitude of antennas are disposed deliver the received RF signals to the rectifying circuit via one or more thru-glass conductors. In one embodiment, the multitude of antennas deliver the received RF signals to the rectifying circuit via an electromagnetic coupler. In one embodiment, the insulated glass unit further includes, in part, one or more of a light sensor, humidity sensor, temperature sensor, vibration sensor, ultrasonic transducer, motion sensor, and occupancy sensor. In one embodiment, the insulated glass further includes, in part, a humidity reduction system disposed within a space separating the first window pane from the second window. The humidity reduction system includes, in part, a desiccant adapted to absorb air molecules, and cathode and anode terminals receiving electrical signal from the controller to perform electrolysis of the air molecules absorbed in the desiccant.

A method of changing an opacity of an insulated glass unit, in accordance with one embodiment of the present disclosure, includes, in part, receiving RF signals via a multitude of antennas disposed on a first window pane of the insulated glass unit; converting the received RF signals to a DC power via a rectifying circuit; and changing the opacity of an electrochromic coating formed on a second window pane of the insulated glass unit using the converted DC power.

In one embodiment, the multitude of antennas are disposed on a first surface of the first window pane exposed to an interior of a room in which the insulated glass unit is adapted to be installed. The rectifying circuit may be disposed on a second surface of the first window pane. In one embodiment, the multitude of antennas and the rectifying circuit are disposed on a surface of the first window pane within a space separating the first window pane from the second window pane.

In one embodiment, the multitude of antennas are formed using a transparent conductive metal layer. In one embodiment, the rectifying circuit is disposed in a frame of the insulated glass unit. In one embodiment, the multitude of antennas are disposed in the frame of the insulated glass unit. In one embodiment, the multitude of antennas deliver the received RF signals to the rectifying circuit via one or more thru-glass conductors. In one embodiment, the multitude of antennas deliver the received RF signals to the rectifying circuit via an electromagnetic coupler.

In one embodiment, the insulated glass unit further includes, in part, one or more of a light sensor, humidity sensor, temperature sensor, vibration sensor, ultrasonic transducer, motion sensor, and occupancy sensor. In one embodiment, the method further includes, in part, absorbing air molecules trapped in a space separating the first and second window panes using a desiccant; and applying an electrical signal across the desiccant to perform electrolysis of the air molecules absorbed in the desiccant, wherein the electrical signal is supplied from the DC power generated by the rectifying circuit.

### BRIEF DESCRIPTION OF THE DRAWINGS

FIG. 1 is a sectional view of an insulated glass unit positioned within a window frame, as known in the prior art.

FIG. 2 is another sectional view of the insulated glass unit shown in FIG. 1 positioned within a window, as known in the prior art.

FIG. 3 is a sectional view of an insulated glass unit, in accordance with one embodiment of the present disclosure.

FIG. 4 is a sectional view of an insulated glass unit, in accordance with one embodiment of the present disclosure.

FIG. 5 is a sectional view of an insulated glass unit, in accordance with one embodiment of the present disclosure.

FIG. 6 is a sectional view of an insulated glass unit, in accordance with one embodiment of the present disclosure.

FIG. 7 is a sectional view of an insulated glass unit, in accordance with one embodiment of the present disclosure.

FIG. 8A shows an insulated glass unit attached to an installed window, in accordance with one embodiment of the present disclosure.

FIG. 8B shows an insulated glass unit attached to an installed window, in accordance with one embodiment of the present disclosure.

FIG. 9 is an example of a patch antenna having a feedline formed on substrate.

FIG. 10 shows components of a humidity reduction system that may be used in an insulated glass unit, in accordance with one embodiment of the present disclosure.

FIG. 11 is a high level block diagram of wireless power delivery and receiving system.

FIG. 12 is a block diagram of a number of components of an RF power generating unit.

FIG. 13 is a block diagram of a controller that may be used in an insulated glass unit, in accordance with one embodiment of the present disclosure.

FIG. 14 is a schematic diagram of a rectifying circuit adapted to convert a an RF signal to a DC voltage, as known in the prior art.

FIG. 15 is a schematic diagram of a rectifying circuit adapted to convert an RF signal to a DC voltage, as known in the prior art.

FIG. 16 is a schematic diagram of a rectifying circuit adapted to convert an RF signal to a DC voltage, as known in the prior art.

FIG. 17 shows a rectenna as may be used in an insulated glass unit, in accordance with one embodiment of the present disclosure.

### DETAILED DESCRIPTION

Aspects of the present disclosure relate to controlling the tint level of an EC glass using wireless power. The EC glass may include a wireless power receiving unit adapted to convert one or more of RF signal, laser beam, infrared signal, or sunlight to electrical energy to control the opacity/translucence of the EC glass.

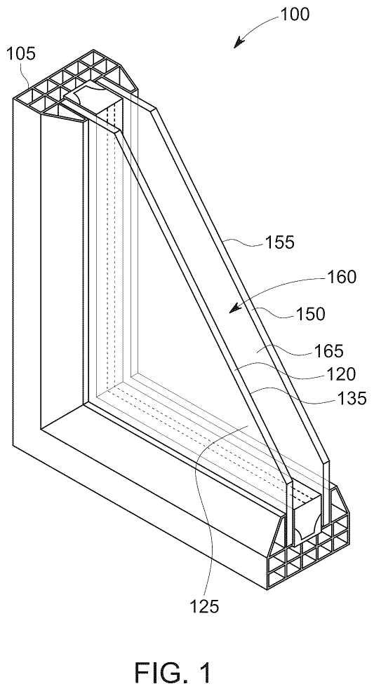

FIG. 1 is a sectional view of an insulated glass unit (IGU) 100 positioned within a window frame 105. IGU 100 is shown as including two glass panes 120 and 150. When installed, glass pane 120 is exposed to the exterior of a building and glass pane 150 is exposed to the interior of the building. Space 160 separates glass pane 120 from glass pane 150. Glass pane 120 includes a first surface 125 that is exposed to the outside and second surface 135 positioned within space 160. Similarly, glass pane 150 includes a first surface 155 that is exposed to the interior of a building, and a second surface 165 positioned within space 160.

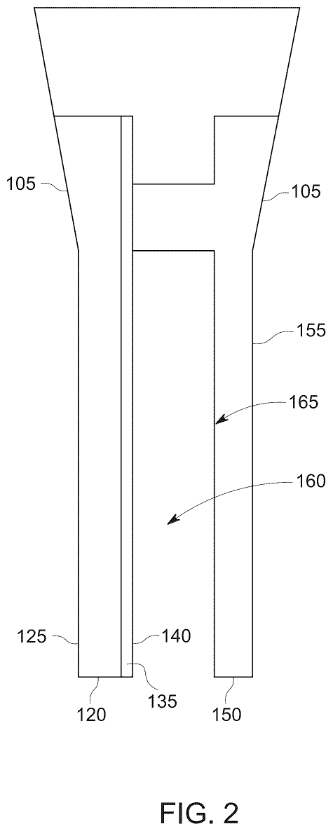

FIG. 2 is another sectional view of IGU 100. In FIG. 2, The EC coating 140 is shown as having been applied to surface 135 to protect the EC coating from the environmental elements, and further to block the heat that is generated by solar rays from reaching the interior of the building. Also shown in FIG. 2, is insulator 105 that insulates/seals space 160 and prevents moisture and other gases from entering space 160.

Electrochromic or other controllable glazing windows (smart glass windows) require electrical power to change or maintain their tint level. Labor intensive wiring requirements of smart glass windows has impeded their wide adoption. While one can avoid the excessive wiring cost by using a battery, the need to replace or recharge the battery periodically discourages adoption of the windows, and may contribute to energy efficiency if the required maintenance is not performed routinely.

In accordance with one aspect of the present disclosure, non-proximity wireless power transmission through the use of radio frequency (RF) and mm-wave beam forming is used to power and thereby change the tint level (alternatively referred to herein as opacity) of a smart glass window. The power received by the glass window is supplied by a wireless power generation unit (GU) that may include, in part, a multitude of synchronized RF sources and antennas, in addition to various other units/components, such as a control/processing unit, a hardware interface unit, and a communications/networking unit. The GU is adapted, among other functions, to generate a focused RF beam and deliver the RF beam wirelessly to the glass window. The focal point of the RF energy is a wireless power receiving unit (RU) placed between a pair of glass windows one of which is an EC glass. The RU receives the RF energy and converts it to electrical energy to control the opacity of the EC glass.

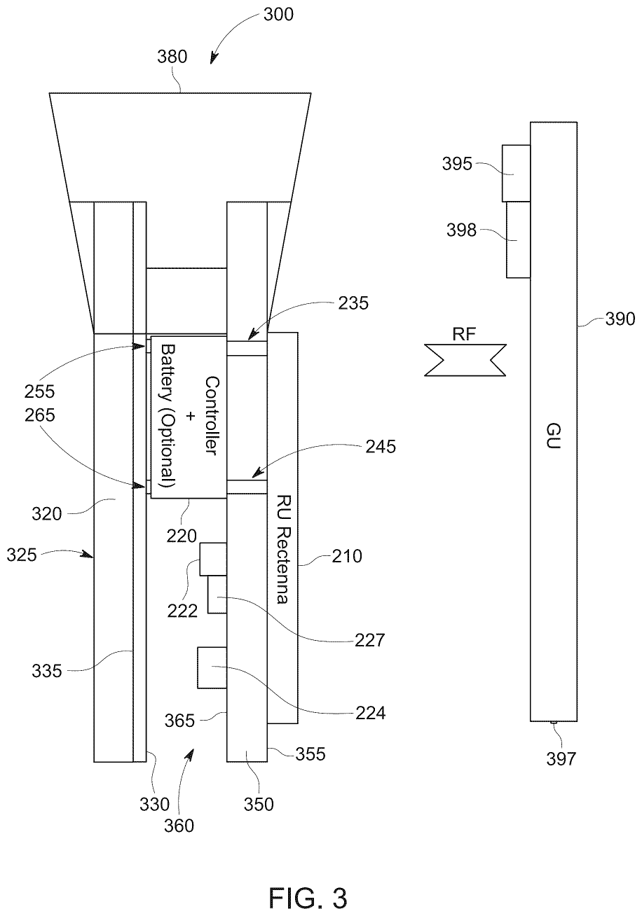

FIG. 3 is a sectional view of an IGU 300, in accordance with one embodiment of the present disclosure. IGU 300 is shown as including, in part, glass windows (panes) 320 and 350 disposed within frame 380. Glass pane 320 is exposed to the exterior of a building and glass pane 350 is exposed to the interior of the building. Space 360 separates glass pane 320 from glass pane 350. Glass pane 320 includes a first surface 325 that is exposed to the outside, and a second surface 335 positioned within space 160. Similarly, glass pane 350 includes a first surface 355 that is exposed to the interior of a building, and a second surface 365 positioned within space 160.

IGU 300 is also shown as including, in part, a controller 220, and a wireless power receiving unit that includes, in part, an array of receive antennas and a rectifier, collectively referred to herein as rectenna, 210. Rectenna 210 receives the focused RF signals generated by GU 390, converts the received RF signals to a DC signal, and delivers the DC signal to controller 220 via thru-glass conductors 235 and 245. In response, controller 220 applies an electrical signal to EC coating 335 via EC busbars 255, 265 to control the opacity of glass pane 320. Controller 220 includes an optional battery used to store the converted electrical energy. Although not shown, the electrical connection between rectenna 210 and controller 220 may be achieved via wires positioned around the edges of the glass and through the IGU sealant. In one embodiment, one or more touch/capacitive sensors, displays, and/or buttons may be integrated on a suitable location on frame 380 to enable a user to control IGU 300.

In some embodiments, GU 390 includes a control unit 395 and a wireless communications system 398 adapted to communicate via, for example, a WiFi, or Bluetooth protocol. IGU 300 may also include a wireless communications system 222. Accordingly, control unit 395 of GU 390 may communicate wirelessly with controller 220 of IGU 300 to, among other functions, adjust the opacity of EC coating 330, via a wireless communications link established between wireless communications systems 222 and 398.

In some embodiments, GU 300 may be in communications with a building management system (e.g., internet, or intranet) either through wireless communications system 398, or through a wired communication system (not shown in FIG. 3). In such embodiments, the building management system (BMS) may compute the level of opacity of EC coating 330, and provide the computed opacity level to GU 300. In response, GU 300 transmits the computed opacity level to controller 220 via wireless communications system 222. Controller 220 then varies the electrical current that controller 220 provides to EC coating 340 via busbars 255 and 265 to achieve the computed opacity level.

In some embodiments, GU 390 may be connected to a data/communications network via an Ethernet cable 397. In such embodiments, GU 300 may receive power from the Ethernet cable using, for example, a Power Over Ethernet (PoE) technology. In some embodiments, GU 390 may be powered by and connected to a data/communications network via a Power Line Communications (PLC) modem.

In some other embodiments, controller 220, via wireless communications system 222, may connect to a cloud network (via internet) or to the building management system (via intranet) either directly, or through a router/gateway, or through a wireless communications system 398 of GU 390, to update its functionality, or receive instructions.

In some other embodiments, IGU 300 may include one or more sensors 224 that are in electrical communication with controller 220. Sensors 224 may include, for example, light sensors to detect the indoor lighting condition, a humidity sensor, a temperature sensor, a vibration sensor adapted to (i) detect potentially damaging impact to glass or (ii) operate as a security sensor, an ultrasonic transducer adapted to detect cracks in the glass or the sealant sealing the glass within the window frame, motion sensor, room occupancy sensor, and the like.

In some embodiments, IGU 300 may include a humidity reduction system 227 disposed in space 360. Humidity reduction system 227 may include one or more of an air pump, heater, and/or vapor electrolysis systems to dispose of the air or moisture that may be trapped in space 360. The air pump may be used to circulate and pump the air out of space 360 from a leak in the sealant that may have provided the opening for the air/moisture to enter into and get trapped in space 360.

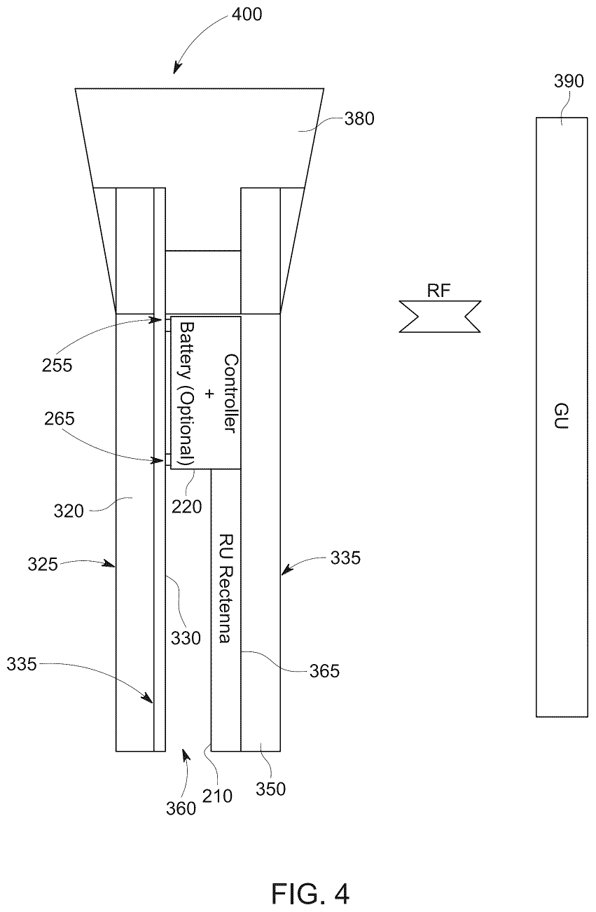

FIG. 4 is a sectional view of an insulated glass unit (IGU) 400, in accordance with another embodiment of the present disclosure. IGU 400 is similar to IGU 300 except that in IGU 400 rectenna 210 is placed within space 360 and on surface 365 of glass pane 350. Accordingly IGU 400 does not include thru-glass conductors 235 and 245. For clarity, not all components of IGU 300 is shown in IGU 400

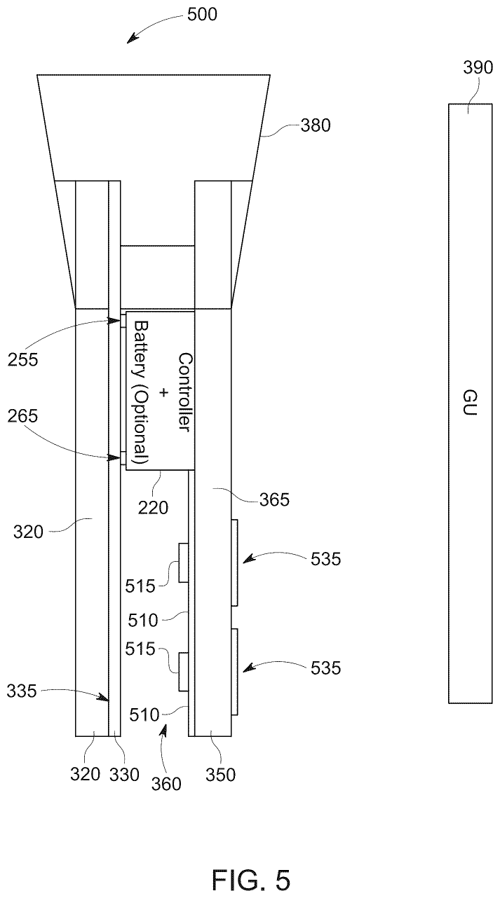

FIG. 5 is a sectional view of an insulated glass unit (IGU) 500, in accordance with another embodiment of the present disclosure. IGU 500 is similar to IGU 300 except for the following differences. For clarity, not all components of IGU 300 is shown in IGU 500. In IGU 500, receive antenna array 535 is integrated in the IGU glass pane 350. Receive antenna array 535 may include solid thin-film metal layers, transparent conducting films such as Indium Tin Oxide (ITO) or semi-transparent nano-wire mesh that is integrated with the glass. Moreover, in IGU 500 the rectifier circuitry 515 is positioned on surface 365 of glass pane 350 and provides the converted DC power to controller 220 via conducting film 510. Controller 220, which includes an optional energy storage (e.g., a battery), controls the opacity of EC coating 330 by applying electric current to the EC coating via busbars 255 and 265.

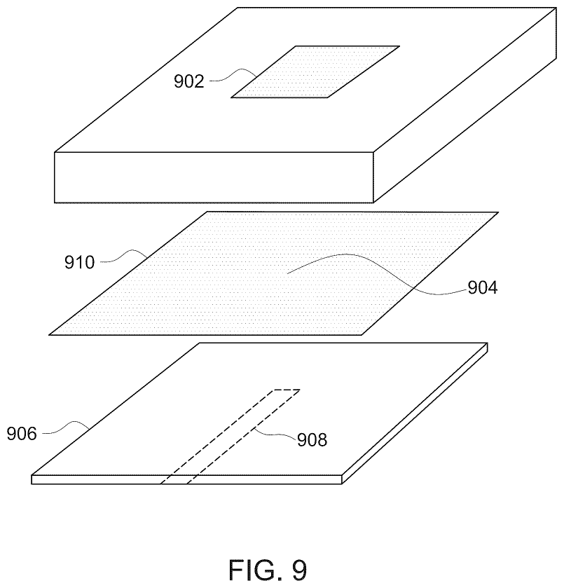

In one embodiment, antennas 535 are patch antennas and are electromagnetically coupled to rectifier 515 using slot coupling. The metal layers in rectifier 515 or the ITO coating on surface 365 can be used to create the slot coupling. FIG. 9 shows an example of a patch antenna 902 having an associated feedline 908 formed on substrate 906. Ground plane 910 includes aperture 904 providing slot coupling to the antenna 902. With reference to FIG. 5, rectifier 535 includes a feedline in a manner similar to that shown in FIG. 9, that delivers the RF power to the rectifying circuit, which include a diode or a transistor. The EC coating layer 330 includes a transparent conducting layer that is used as a reflector for the antenna. By adjusting the spacing between patch antenna 535 and the EC coating layer (reflector) 330, the phase of reflected signals arriving at rectifier 515 may be controlled, in accordance with one aspect of the present disclosure, to form an inductive, capacitive, or resistive source impedance to rectifier 515 to achieve impedance matching.

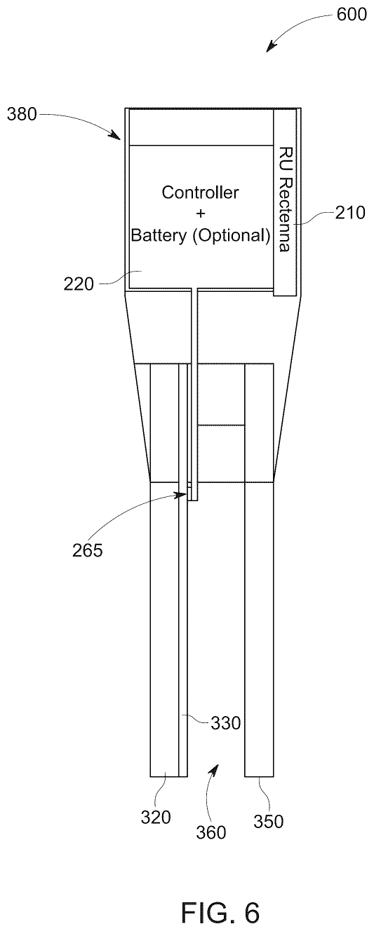

FIG. 6 is a sectional view of an insulated glass unit (IGU) 600, in accordance with another embodiment of the present disclosure. IGU 600 is similar to IGU 300 except that in IGU 600, controller 220 that includes the optional energy storage 220, as well as RU rectenna 210 are embedded within the fame 380 of the IGU. The RF signal passes through frame 380 to imping on the receive antennas disposed in rectenna 210. For clarity, not all components of IGU 300 is shown in IGU 600.

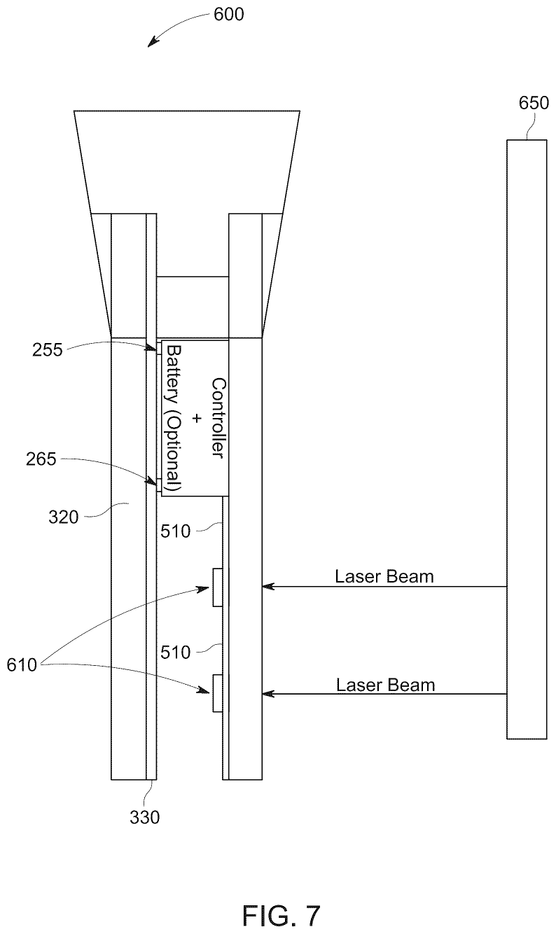

FIG. 7 is a sectional view of an insulated glass unit (IGU) 700, in accordance with another embodiment of the present disclosure. IGU 700 includes one or more photovoltaic cells 610 each adapted to convert a laser beam to a DC power that is delivered to controller 220 via conducting film 510. The controller uses the DC power received from the photovoltaic cells to control the opacity of EC coating 330. The laser beam is provided by laser source 650. In some embodiments, the photovoltaic cells of IGU 600 are positioned to convert the sunlight to electrical energy thus dispensing with the need for the laser source 650.

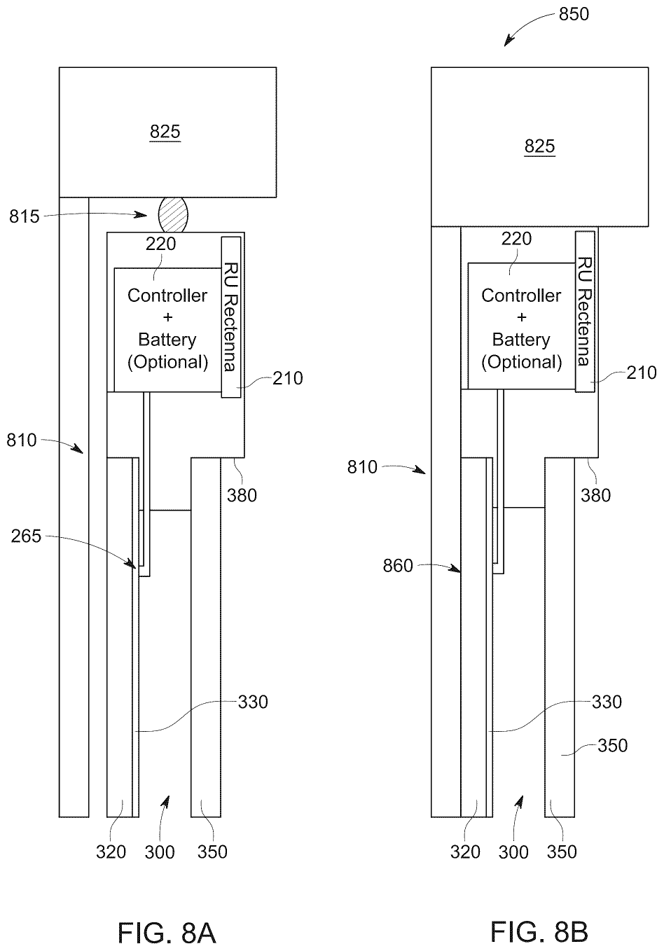

In some embodiments, the IGU and framing are adapted to attach to an installed glass window without the need for removing the installed glass window. The IGU can attach to the existing glass via transparent adhesive, edge clips, fasteners or screws. FIG. 8A shows an IGU attached to an installed window 810, in accordance with one embodiment of the present disclosure. The IGU has a frame 380 that is attached to window 810's frame 825 by robber gasket or adhesive 815. The IGU is shown as including window panes 320 and 350. EC coating 330 is disposed on window pane 320. Controller 220 and rectenna 210 of the IGU are shown as having been disposed in frame 380. However, controller 220 and rectenna 210 of the IGU may be disposed in other positions within the IGU as shown in other Figures and described above.

FIG. 8B shows an IGU attached to an installed window 810, in accordance with another embodiment of the present disclosure. The IGU is shown as including window panes 320 and 350. EC coating 330 is disposed on window pane 320. Controller 220 and rectenna 210 of the IGU are shown as having been disposed in frame 380. However, controller 220 and rectenna 210 of the IGU may be disposed in other positions within the IGU as shown in other Figures and described above. Window pane 320 is attached to installed window 810 using adhesive 860.

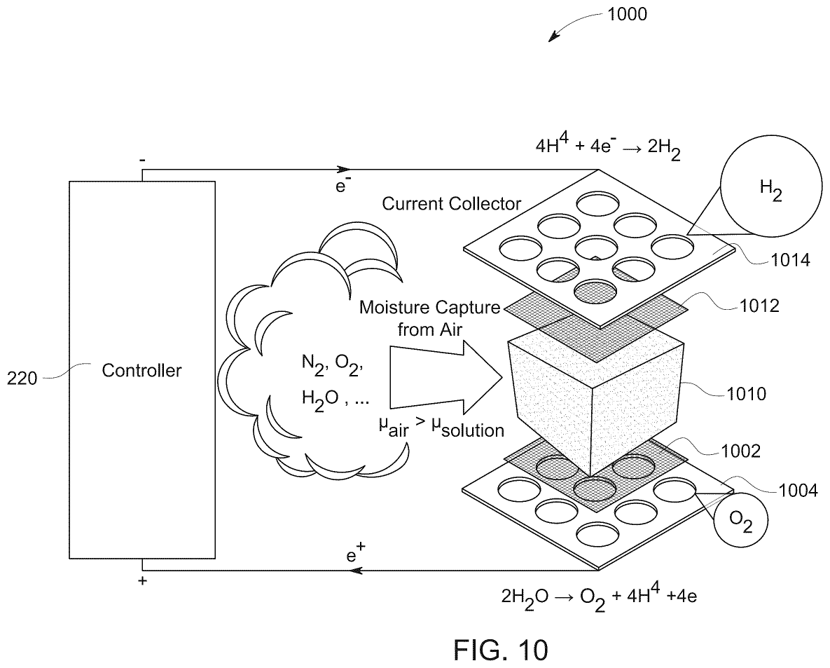

FIG. 10 shows components of a humidity reduction system 1000, as was also described above with reference to FIG. 1 and identified using reference number 227. Humidity reduction system 8100 is adapted to perform electrolysis to convert the air molecules into Oxygen and Hydrogen gases that, in part, pressurize space 360 thus forcing the gases to exit from a faulty leak in the sealant that was used as a passage for the air molecules to enter space 360 in the first place. Humidity reduction system 1000, which may be disposed in space 360 between the two window panes 350 and 320, is shown as including, in part, a desiccant (such as a sponge) 1010 adapted to absorb the water molecules. Wire mesh 1012 and conductive pad 1014 form the cathode of the electrolysis system, and wire mesh 1002 and conductive pad 1014 form the anode of the electrolysis system. As the electrical current that is supplied by controller 220 passes from the cathode to the anode, it separates the water molecules in desiccant 1010 to Hydrogen and Oxygen gases which then exist the space in which they are trapped.

A GU, in accordance with any of the embodiments shown above, can transmit and transfer power in different directions and orientations and can change the direction and orientation rapidly and effectively, with relatively small power spill-over, i.e., power that is not recovered and is thus wasted. The GU achieves maximum power transfer by setting a combination of phases of the RF power sources on the GU that maximizes the energy concentration for a given RU location and orientation.

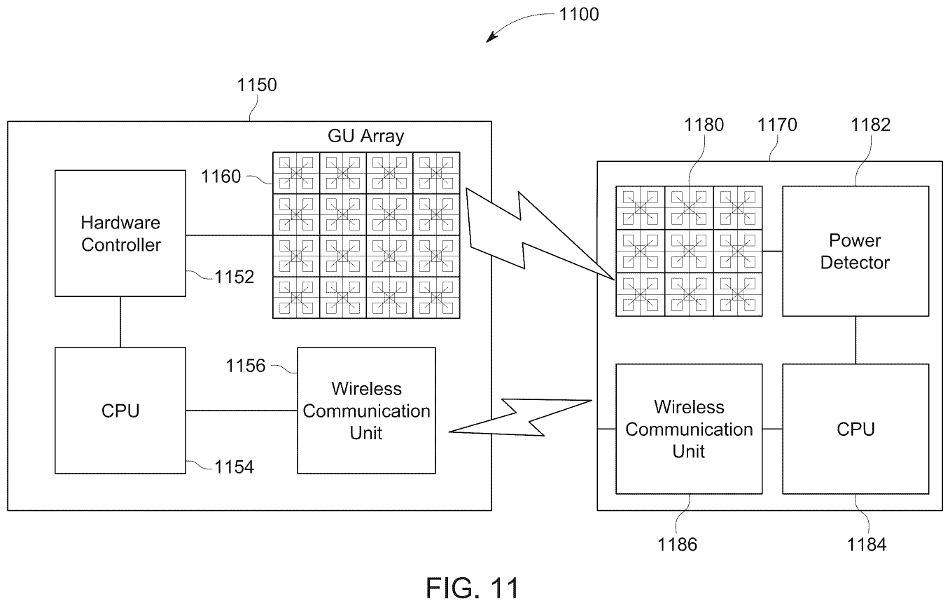

FIG. 11 is a high level block diagram of wireless power delivery and receiving system 1100 having a GU 1150 adapted to deliver multiple outputs with independently controlled phases and amplitudes from a single reference signal to RU 1170. GU 1150 is shown as including an array of transmit antennas 1160, a controller 1150, a processing unit 1154 and a wireless communication unit 1156. The transmit antenna array delivers RF signals whose phases are adjusted to cause constructive interference at the position of the wireless power receiving unit 1170. The phases of the RF signals are controlled by hardware controller 1152 and processing unit 1154. GU 1150 communicates with RU 1170 via wireless communication unit 1156. RU 370 is shown as including an array of receiving antennas 380, a power detector 382, a processing unit 384 and a wireless communication unit 1186 that communicates with wireless communication unit 1156. The receive antenna array 1170 receives the RF signals transmitted by GU 1150. Power detector 382 is adapted to detect the amount of power being received by RU 1170 from GU 1150 and transmit the amount of received power to GU 1150 to enable GU adjust phases of the Rf signals its transmits to improve power delivery to RU 1170.

For any given effective GU aperture area, AG, an effective RU aperture area, AR, the distance between the GU and the RU, D, and the wavelength of operation, A, the transfer efficiency, namely the ratio of the power incident on the RU aperture to the power transmitted by the GU can be approximated as:

$$η = \frac{{P}_{R U}}{{P}_{G U}} \approx 1 - {e}^{- r} \qquad ( 1 )$$

$$where e = \frac{{A}_{G} {A}_{R}}{{( λ D )}^{2}} \qquad ( 2 )$$

At large distances, the transfer efficiency may be estimated to be equal to r, namely:

$$η = \frac{{P}_{R U}}{{P}_{G U}} = \frac{{A}_{G} {A}_{R}}{{( λ D )}^{2}} \qquad ( 3 )$$

In the above equations it is assumed that the GU's and RU's apertures are facing each other, i.e., they are both perpendicular to the axis connecting their centers. In practice, multiple devices whose RU's are to be charged using the GU may be at different locations and orientations with respect to the GU.

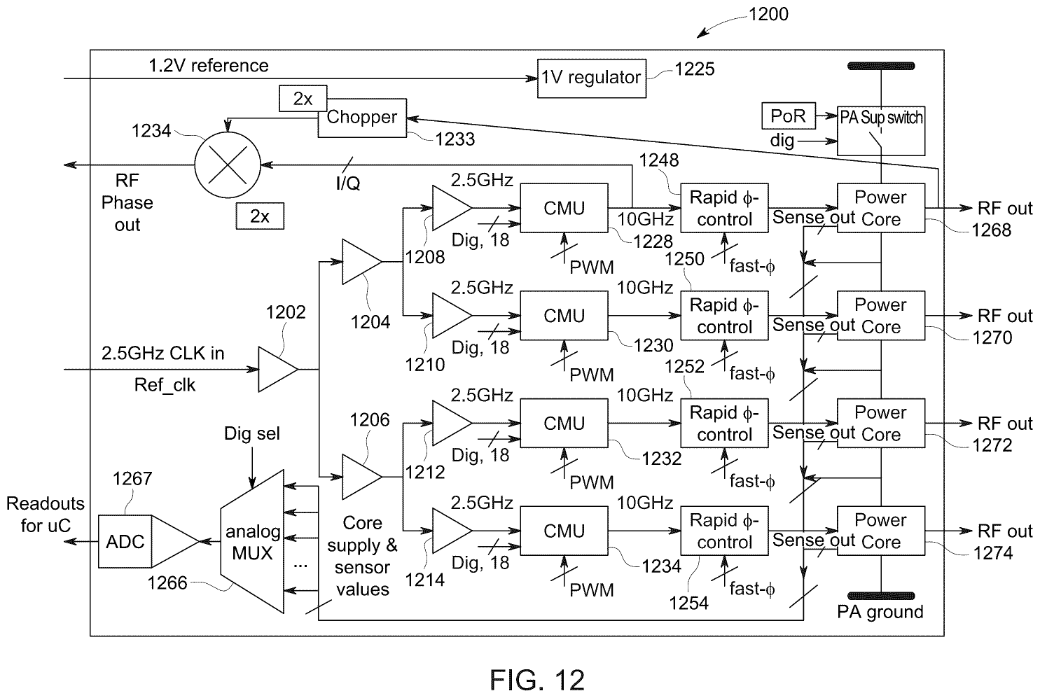

FIG. 12 is a block diagram of a number of components of an RF power generating unit 1200, in accordance with one exemplary embodiment of the present disclosure. Reference clock signal Ref_clk is buffered by buffers 1202m 1204, 1206m 1208, 1210, 1212 and 1214 and multiplied by clock multiplier units (CMU) 1228, 1230, 1232 and 1234. In this example, the reference clock is shown as being a 2.5 GHz that is multiplied by the CMUs to generate a multitude of 10 GHz clocks. In addition to clock multiplication, each CMU is adapted to shift the phase of the clock signal it receives to generate a phase-shifted clock signal that in this example is shown as having a frequency of 10 GHz.

Each of rapid phase control units 1248, 1250,\ 1252 and 1254 is adapted to relatively quickly switch the phase of the clock signal it receives when RF power generating unit 1200 uses time interleaving to power two devices in a time-interleaved manner. Each of the power cores 1268, 1270, 1272 and 1274 is adapted to amplify the signal it receives from an associated rapid phase control unit and transmit the amplified RF signal via an associated antenna not shown in FIG. 12. The antennas also operate as receive antennas for communication with the power receiving unit or for detecting a signal reflected from an object or a living organism. Chopper 1233 and mixer 1234 are adapted to downconvert the frequency of the received RF signal and cancel out the 1/f noise of the received signal. Analog multiplexer 1266 is adapted to sense the signals generated by the power cores. The sensed signals are converted to digital signals by ADC 1267 and used by a controller to ensure the power cores receive substantially similar current/voltage. The various components shown in FIG. 12 are powered by voltage regulator 1225 which in this example is shown as receiving a 1.2 reference voltage and converting it to a 1 volt regulated voltage.

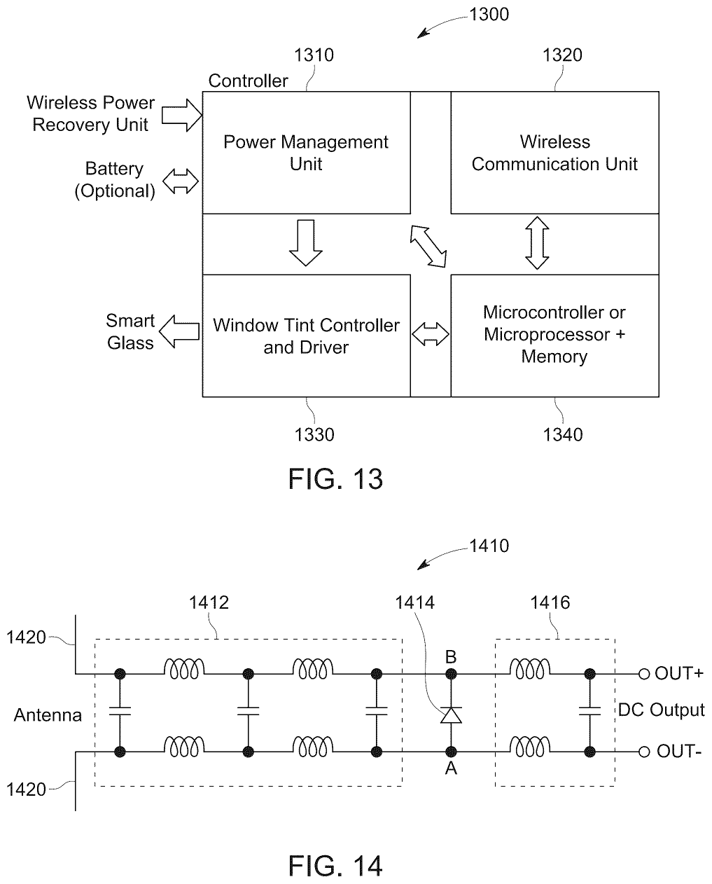

FIG. 13 is a block diagram of a controller 1300 used in an IGU, in accordance with one embodiment of the present disclosure. Controller 1300 corresponds to any of the controllers described above, such as controller 220 describe with reference to Figure. Power management unit 1310 is adapted to receive the power supplied by the power recovery unit (rectenna). Power management unit 1310 may include an optional battery to store the received power. Wireless communication unit 1320 is used to communicate with the GU, connect to internet, intranet, BMS, and the like, as described above. Microcontroller/microprocessor 1340, which includes a memory, controls the various activities of controller 1330, such as determining the tint level, instructing the wireless communication unit 1320 to establish a communications link, instructing the power management unit to store the received power, or supply power from the battery. Window tint controller and driver provides the current required to set the opacity of the EC coating by receiving power from power management unit 1310 and in accordance with instructions received from microcontroller 1340.

FIG. 14 is a schematic diagram of a rectifying circuit 1410 adapted to convert an RF signal received via antenna 1420 to a DC voltage across terminals OUT+ and OUT−. Circuit 1410 is shown as including a matching LC network 1412, a Schottky diode 1414 and a RF bypass network 1416. During one-half of each cycle when the anode terminal A of diode 1414 has a higher potential than its cathode terminal B, diode 1414 become conductive thus causing the received energy to be stored in electric and magnetic fields inside the matching network 1412. During the other half of each cycle, diode 1414 becomes non-conductive and the stored energy in matching network 1412 as well as the incident energy are supplied across output terminals OUT⁺ and OUT⁻.

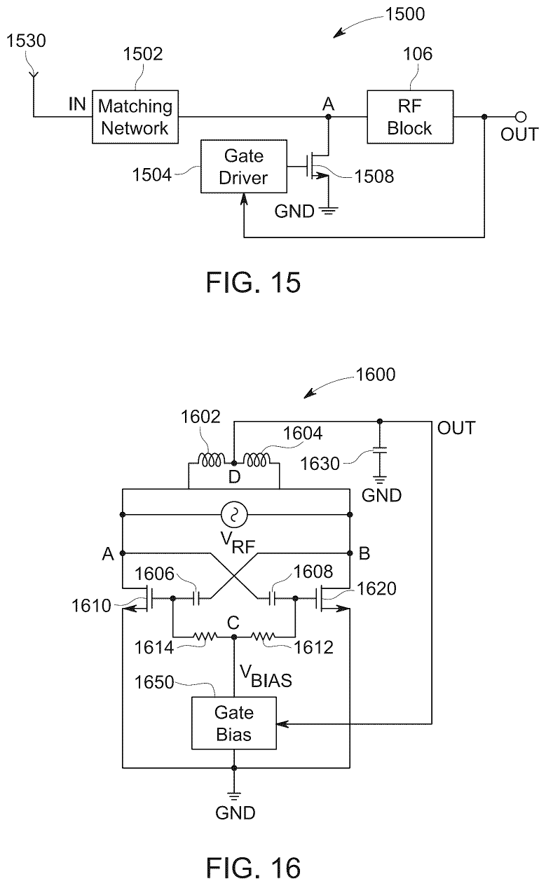

FIG. 15 is a schematic diagram of a CMOS rectifying circuit 1500. CMOS rectifying circuit 1500 is shown as including, in part, a matching network 1502, a gate driver (gate driving circuit) 1504, an RF blocker (blocking circuit) 1506, and an N-channel MOS (NMOS) transistor 1508. Antenna 1530 receives the incident electromagnetic (EM) wave and applies the received RF signal via input terminal IN to circuit 1500.

Matching network 1502 is adapted to provide impedance matching between the antenna and the drain node A of transistor 1508. It is understood that any number of matching networks may be used to provide such impedance matching. RF blocker 1506 is adapted to block the received RF signal from reaching the output terminal OUT. It is understood that any number of RF blocking circuits may be used to inhibit the RF signal from arriving at the output terminal OUT. Gate driver 1504 is adapted to sense the output voltage present at output terminal OUT and in response control the DC and AC components of the voltage applied to the gate of NMOS transistor 1508 dynamically to achieve optimum operating performance metrics, such as efficiency, output voltage, load, and the like.

During one-half of each cycle when the voltage supplied at input terminal IN is positive relative to the ground potential (received by the source terminal of transistor 1508) because transistor 1508 is on, the current delivered to node A by matching network 1502 flows to the ground GND. During the other half of each cycle, when the voltage supplied at input terminal IN is negative relative to the ground potential, a DC current is enabled to flow from the ground terminal GND to output terminal OUT via node A and RF blocking circuit 1506. The voltage at terminal OUT is therefore rectified.

FIG. 16 is a schematic diagram of a rectifying circuit 1600 adapted to rectify RF voltage VRF supplied by an antenna (not shown) in response to incident RF signal. Rectifying circuit 1600 is shown as including, in part, inductors 1602, 1604, capacitors 1606, 1608, 1630, resistors 1614, 1612, NMOS transistors 1610, 1620, and optional gate driver circuit 1650.

Inductors 1602, 1604 form a matching network in the differential mode between drain terminals (i.e., nodes A and B) of transistors 1610, 1620 and the antenna ports (not shown) supplying differential RF signal VRF to nodes A and B. Inductors 1602, 1604 partly offset the parasitic capacitance of transistors 1610, 1620, and together with capacitor 1630 form a low pass filter, thereby filtering out voltage ripples that would otherwise appear at the output terminal OUT.

During the common mode, inductors 1602, 1604 and capacitor 1630 form an RF blocking circuit by causing the RF signal to be shunted to the ground terminal GND and thus blocking the RF signal from reaching the output terminal Out. In one embodiment gate driver circuit 1650 may include a battery. In another embodiment, gate driver circuit 1650 is adapted to sense the output voltage at terminal OUT and in response apply biasing voltage VBias to the gate terminals of transistors 1610, 1620 via resistors 1614, 1612. Resistors 1614 and 1612 are selected to have relatively high resistances so as to cause relatively low voltage drop. Accordingly, the DC voltage supplied to the gate terminals of transistors 1610, 1620 is substantially similar to voltage VBias.

The DC voltage VBias generated by gate driver circuit 1650 is set to a value that places transistors 1610 and 1620 at the onset of conduction. During one-half of each cycle when node A has a higher voltage than node B (as supplied by the antenna), transistor 1620 turns on and transistor 1610 turns off. Conversely, during the other half of each cycle when node A has a lower voltage than node B, transistor 1620 turns off and transistor 1610 turns on. Capacitors 1606 and 1608 prevent the current supplied by gate driver 1650 from flowing into nodes A and B.

As described above, during one-half of each cycle when node A has a higher voltage than node B, transistor 1620 is turned on and transistor 1610 turns off. Accordingly, during such cycles, current is caused to flow from the ground terminal GND to terminal OUT via transistor 1620 and inductor 1604. During the other half of each cycle when node A has a lower voltage that node B, transistor 210 is turned on and transistor 1620 is turned off. Accordingly, during such cycles, current is caused to flow from the ground terminal GND to terminal OUT via transistor 1610 and inductor 1602.

As described above, gate driver circuit 1650 is adapted to sense the output voltage at terminal OUT and in response vary the biasing voltage it applies to gate terminals of transistors 1610, 1620. This biasing voltage is varied until the voltage at terminal OUT reaches a predefined value. If the incident RF signal is relatively too strong, it may cause damage to transistors 1610, 1620. Intrinsic or extrinsic protection mechanisms may thus be used to improve the reliability and longevity of rectifying circuit 1600. Such protection may be provided at different levels ranging from the top-level system, to various blocks and individual circuits. For example, when the output voltage exceeds a predefined value, gate driver circuit 1650 increases the voltage applied to the gate terminals of transistors 1610, 1620 to a maximum possible value to lower the resistances from nodes AB to the ground, thereby to shut down the rectifying operation of rectifying circuit 1600. The rectifying circuit may use wireless communication to instruct the transmitter to lower its power.

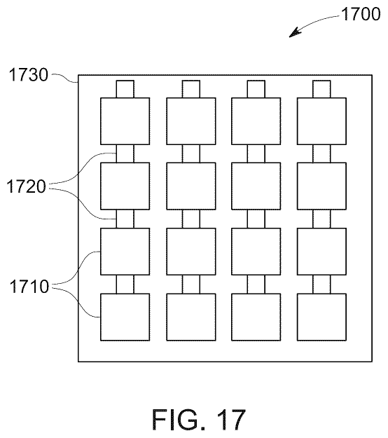

FIG. 17 shows a rectenna 1700 as may be used in any of the embodiments of the IGUs described above. Rectenna 1700 is shown as including, in part, a multitude of patch antennas 1710 adapted to receive the RF signals transmitted by a GU. Rectenna 1700 is also shown as including, in part, rectifying circuitry 1720 disposed on a printed circuit board 1730.

The above embodiments of the present invention are illustrative and not limitative. Other additions, subtractions or modifications are obvious in view of the present disclosure and are intended to fall within the scope of the appended claims.

1. An insulated glass unit comprising:
a first window pane comprising an electrochromic coating;
a second window pane spaced away from the first window pane and comprising:
a plurality of antennas adapted to receive RF signals;
a rectifying circuit adapted to convert the RF signals received by the plurality of planar antennas to a DC power; and
a controller adapted to change an opacity of the electrochromic coating from the converted DC power.

2. The insulated glass unit of claim 1 wherein the plurality of antennas are disposed on a first surface of the second window pane exposed to an interior of a room in which the insulated glass unit is adapted to be installed, and wherein the rectifying circuit and the controller are disposed on a second surface of the second window pane.

3. The insulated glass unit of claim 1 wherein the plurality of antennas, the rectifying circuit and the controller are disposed on a surface of the second window pane within a space separating the first window pane from the second window pane.

4. The insulated glass unit of claim 1 wherein the plurality of antennas are formed using a transparent conductive metal layer.

5. The insulated glass unit of claim 1 wherein the rectifying circuit and the controller are disposed in a frame of the insulated glass unit.

6. The insulated glass unit of claim 5 wherein the plurality of antennas are disposed in the frame of the insulated glass unit.

7. The insulated glass unit of claim 2 wherein the plurality of antennas deliver the received RF signals to the rectifying circuit via one or more thru-glass conductors.

8. The insulated glass unit of claim 2 wherein the plurality of antennas deliver the received RF signals to the rectifying circuit via an electromagnetic coupler.

9. The insulated glass unit of claim 1 further comprising one or more sensors selected from a group consisting of light sensor, humidity sensor, temperature sensor, vibration sensor, ultrasonic transducer, motion sensor, and occupancy sensor.

10. The insulated glass unit of claim 1 further comprising a humidity reduction system disposed within a space separating the first window pane from the second window, the humidity reduction system comprising:
a desiccant adapted to absorb air molecules, and
cathode and anode terminals receiving electrical signal from the controller to perform electrolysis of the air molecules absorbed in the desiccant.

11. A method of changing an opacity of an insulated glass unit comprising:
receiving RF signals via a plurality of antennas disposed on a first window pane of the insulated glass unit;
converting the received RF signals to a DC power via a rectifying circuit; and
changing the opacity of an electrochromic coating formed on a second window pane of the insulated glass unit using the converted DC power.

12. The method of claim 11 wherein the plurality of antennas are disposed on a first surface of the first window pane exposed to an interior of a room in which the insulated glass unit is adapted to be installed, and wherein the rectifying circuit is disposed on a second surface of the first window pane.

13. The method of claim 11 wherein the plurality of antennas and the rectifying circuit are disposed on a surface of the first window pane within a space separating the first window pane from the second window pane.

14. The method of claim 11 wherein the plurality of antennas are formed using a transparent conductive metal layer.

15. The method of claim 11 wherein the rectifying circuit is disposed in a frame of the insulated glass unit.

16. The method of claim 15 wherein the plurality of antennas are disposed in the frame of the insulated glass unit.

17. The method of claim 12 wherein the plurality of antennas deliver the received RF signals to the rectifying circuit via one or more thru-glass conductors.

18. The method of claim 2 wherein the plurality of antennas deliver the received RF signals to the rectifying circuit via an electromagnetic coupler.

19. The method of claim 11 wherein the insulated glass unit comprises one or more sensors selected from a group consisting of light sensor, humidity sensor, temperature sensor, vibration sensor, ultrasonic transducer, motion sensor, and occupancy sensor.

20. The method of claim 11 further comprising:
absorbing air molecules trapped in a space separating the first and second window panes using a desiccant; and
applying an electrical signal across the desiccant to perform electrolysis of the air molecules absorbed in the desiccant, wherein the electrical signal is supplied from the DC power generated by the rectifying circuit.

21. The insulated glass unit of claim 1 further comprising:
a wireless communications system adapted to establish a communications link with the Internet or a building management system.

22. The insulated glass unit of claim 21 wherein the controller is adapted to change the opacity of the electrochromic coating in accordance with data received by the wireless communications system.

23. The insulated glass of claim 1 further comprising:
a power generating unit adapted to generate the RF signals received by the plurality of planar antennas.

24. The insulated glass of claim 21 wherein the controller is adapted to change the opacity of the electrochromic coating in accordance with data transmitted from the power generating unit to the wireless communications system.

25. An insulated glass unit comprising:
a first window pane comprising an electrochromic coating;
a second window pane spaced away from the first window pane and comprising:
a plurality of photovoltaic cells adapted to convert light to a DC voltage; and
a controller adapted to change an opacity of the electrochromic coating from the converted DC power.
